(19) United States
(12) Patent Application Publication
(10) Pub. No.: US 2015/0228862 A1
(43) Pub. Date: Aug. 13, 2015

(54) LED ELEMENT, AND PRODUCTION METHOD THEREFOR

(71) Applicant: USHIO DENKI KABUSHIKI KAISHA, Tokyo (JP)

(72) Inventors: Kohei Miyoshi, Himeji-shi (JP); Masashi Tsukihara, Himeji-shi (JP)

(73) Assignee: USHIO DENKI KABUSHIKI KAISHA, Tokyo (JP)

(21) Appl. No.: 14/428,168

(22) PCT Filed: Sep. 5, 2013
(86) PCT No.: PCT/JP2013/073931

§ 371 Date: Mar. 13, 2015

(30) Foreign Application Priority Data
Sep. 18, 2012 (JP) 2012-204924

(51) Int. Cl. H01L 33/42; H01L 33/40; H01L 33/32; H01L 33/00

(52) U.S. Cl. CPC H01L 33/42; H01L 33/0033; H01L 33/405; H01L 33/32; H01L 2933/0016

(57) ABSTRACT

The LED element has a conductive layer formed on the upper layer of the support substrate; a conductive oxide film layer formed on the upper layer of the conductive layer and made of a material having a thermal expansion coefficient of 1×10⁻⁶/K or more and 1×10⁻⁵/K or less; a light-emitting layer; a third semiconductor layer made of an n-type nitride semiconductor formed on the upper layer of the light-emitting layer; and an electrode formed at a position facing the conductive oxide film layer in a vertical direction so that a bottom surface of the electrode is in contact with a portion of an upper surface of the third semiconductor layer.

### TECHNICAL FIELD

The present invention relates to an LED element and a production method therefor, and more particularly to a longitudinal-type LED element made of a nitride semiconductor and a production method therefor.

### BACKGROUND ART

Conventionally, in an LED made of a nitride semiconductor, GaN is mainly used. In this case, from the viewpoint of lattice matching, a GaN film having few defects is formed on a sapphire substrate by epitaxial growth, so as to form an LED element made of a nitride semiconductor. Here, the sapphire substrate is an insulating material, so that, for the purpose of supplying electric power to a GaN-based LED, the n-layer is exposed by cutting a part of the p-layer to form an electrode for power supply on each of the p-layer and the n-layer. The LED having a structure such that the electrodes for power supply are arranged in the same direction is referred to as a lateral-type structure, and such a technique is disclosed, for example, in the following Patent Document 1.

On the other hand, for the purpose of improving the light emission efficiency and achieving more efficient light extraction of the LED element, development of an LED having the so-called longitudinal-type structure in which the p-layer and the n-layer are arranged on the front and back surfaces to provide power supply is advanced. In producing an LED having this longitudinal-type structure, the n-layer and the p-layer are arranged on the upper layer of the sapphire substrate sequentially from below and, after a support substrate made of silicon (Si) or copper tungsten (CuW) is bonded to the p-layer side, the sapphire substrate is removed. In this case, the element front surface will be the n-layer side, and the power supply is carried out by disposing a bonding electrode as an electrode for power supply on this n-layer and connecting a wire, which is a power supply line, onto this bonding electrode (wire bonding). For example, the following Patent Document 2 discloses such a technique.

Also, for the purpose of increasing the light emission efficiency, this Patent Document 2 discloses a construction in which an insulating layer is disposed on an electrode on the p-layer side at a position facing vertically downward to the bonding electrode.

In the case in which the insulating layer is not formed, when a voltage is applied between the electrode on the p-layer side and the bonding electrode (which is also the electrode on the n-layer side), a current path in the vertical direction in which the current flows almost by the shortest distance from the electrode on the p-layer side (hereafter referred to as “p-side electrode”) towards the bonding electrode (hereafter referred to as “n-side electrode”) is formed. Because a semiconductor layer including the light-emitting layer is formed between these two electrodes, flow of a current is concentrated at a site sandwiched between these two electrodes even within the light-emitting layer. As a result of this, the current does not flow in a wide range within the light-emitting layer with respect to the horizontal direction, whereby the light-emitting region is restricted, and the amount of light extracted from the LED element becomes extremely small.

By disposing an insulating layer on the p-side electrode at a position facing the n-side electrode with respect to the vertical direction as disclosed in Patent Document 2, the situation in which the position of the p-side electrode and the n-side electrode that are in contact with the semiconductor layer are arranged in a positional relationship of facing each other in the vertical direction via the semiconductor layer including the light-emitting layer is avoided. At this time, when a voltage is applied between the two electrodes, a current flows from the p-side electrode towards the n-side electrode via a current path having a certain width in the horizontal direction within the light-emitting layer. This allows that the region where the current flows within the light-emitting layer is widened in the horizontal direction, resulting in increase of the light emission efficiency of the LED element.

### PRIOR ART DOCUMENTS

### Patent Documents

Patent Document 1: Specification of Japanese Patent No. 2976951

Patent Document 2: Specification of Japanese Patent No. 4207781

### SUMMARY OF THE INVENTION

### Problems to be Solved by the Invention

However, by eager researches made by the present inventors, it has been found out that, when an LED element is produced with forming an insulating layer at a position where the electrodes face each other so that a current may flow in a wide range in the horizontal direction within the light-emitting layer, cracks or exfoliation may possibly be generated at an interface between the insulating layer and the p-side electrode.

As the above-described insulating substance, SiO₂ is typically used. The thermal expansion coefficient of SiO₂ shows a low value of about 5×10⁻⁷/K. On the other hand, Ag is typically used as the p-side electrode. The thermal expansion coefficient of Ag is about 2×10⁵/K, so that there is a discrepancy of a multiple of about 40 times between the two.

In the meantime, when bonding the support substrate to the p-layer side, a high temperature is given to the element. At this time, there is a large difference in the degree of expansion between the p-side electrode (Ag) having a high thermal expansion coefficient and the insulating layer (SiO₂) having a low thermal expansion coefficient that is in contact with this p-side electrode. Therefore, when the heating step is finished and the element is cooled, cracks or exfoliation can be generated at this interface due to the difference between the compression stress of the p-side electrode and the compression stress of the insulating layer. When such cracks or exfoliation is generated, the LED element itself comes to stop operating normally, thereby failing to achieve an original object of forming the insulating layer for allowing horizontal widening of the current flowing within the light-emitting layer to increase the light emission efficiency.

On the other hand, by adopting a construction in which this SiO₂ film is not formed, problems such as cracks or exfoliation at the interface as described above are eliminated; however, the site of light emission is restricted due to the current flowing at a limited site within the light-emitting layer, so that the amount of light extracted from the LED element becomes extremely small.

In view of the above-described problems, an object of the present invention is to provide an LED element that does not invite a situation such as cracks or exfoliation at a layer interface at the time of production while ensuring horizontal-direction widening of a current flowing within the light-emitting layer to achieve high light emission efficiency, as well as a production method therefor.

### Means for Solving the Problems

The LED element of the present invention is an LED element containing a nitride semiconductor, comprising:

a support substrate made of a conductor or a semiconductor;

a conductive layer formed on the upper layer of the support substrate;

a conductive oxide film layer formed on the upper layer of the conductive layer;

a first semiconductor layer made of a p-type nitride semiconductor formed so that a bottom surface of the first semiconductor layer is in contact with a portion of an upper surface of the conductive layer and a portion of an upper surface of the conductive oxide film layer;

a second semiconductor layer formed on the upper layer of the first semiconductor layer and made of a p-type nitride semiconductor having a lower concentration than that of the first semiconductor layer;

a light-emitting layer made of a nitride semiconductor formed on the upper layer of the second semiconductor layer;

a third semiconductor layer made of an n-type nitride semiconductor formed on the upper layer of the light-emitting layer; and

an electrode formed at a position facing the conductive oxide film layer in a vertical direction so that a bottom surface of the electrode is in contact with a portion of an upper surface of the third semiconductor layer, wherein

the conductive oxide film layer is made of a material having a thermal expansion coefficient of 1×10⁻⁶/K or more and 1×10⁻⁵/K or less.

According to the above construction, the difference in the thermal expansion coefficient between the conductive oxide film layer formed at a part that is in contact with the p-type first semiconductor layer and the conductive layer formed therebelow can be reduced. This allows that, even in a case in which a heating treatment is carried out in the production process, no cracks or exfoliation is generated at the interface between the conductive layer and the conductive oxide film layer due to the difference in thermal expansion coefficient.

This conductive oxide film layer is more preferably made of a material having a thermal expansion coefficient of 3×10⁻⁶/K or more and 8×10⁻⁶/K or less.

Also, with respect to the vertical direction, the conductive oxide film layer is formed on the lower layer of the p-type first semiconductor layer at a position facing the electrode (hereafter occasionally referred to as “n-side electrode”) formed on the upper layer of the n-type third semiconductor layer. Although having a smaller specific resistance as compared with an insulating layer such as SiO₂, the conductive oxide film layer can be made to have a specific resistance of about hundred times as large as that of the conductive layer (for example, Ag, hereafter occasionally referred to as “p-side conductive layer”) formed on the lower layer of the first semiconductor layer. For this reason, when a voltage is applied between the p-side conductive layer and the n-side electrode, a current flows along a current path that goes from the p-side conductive layer formed at a site that is in contact with the p-type first semiconductor layer towards the n-side electrode via the light-emitting layer. The conductive oxide film layer is formed on the upper layer of the p-side conductive layer at a site facing the n-side electrode in the vertical direction. In other words, the p-side conductive layer is in contact with the first semiconductor layer at a position that does not face the n-side electrode in the vertical direction. As a result of this, when a voltage is applied between the p-side conductive layer and the n-side electrode, the current can be let to flow via a current path having a certain width in the horizontal direction within the light-emitting layer, whereby the region where the current flows within the light-emitting layer is widened in the horizontal direction to increase the light emission efficiency of the LED element.

In other words, the above construction makes it possible to prevent inviting a situation such as cracks or exfoliation at a layer interface at the time of production while ensuring horizontal-direction widening of a current flowing within the light-emitting layer.

The LED element described above can be formed by passing through the following steps. In other words, the production method includes:

a step (a) of preparing a sapphire substrate;

a step (b) of forming the third semiconductor layer, the light-emitting layer, the second semiconductor layer, and the first semiconductor layer on the upper layer of the sapphire substrate in this order from below;

a step (c) of forming a conductive oxide film layer made of a material having a thermal expansion coefficient of 1×10⁻⁶/K or more and 1×10⁻⁵/K or less at a first predetermined site of an upper layer of the first semiconductor layer;

a step (d) of forming a conductive layer so as to cover an exposed portion of an upper surface of the first semiconductor layer and an upper surface of the conductive oxide film layer;

a step (e) of bonding a bottom surface of a support substrate made of a conductor or a semiconductor onto an upper surface of the conductive layer directly or via another conductive layer;

a step (f) of exfoliating the sapphire substrate by radiating laser light from above in a state in which the support substrate is positioned at a bottom and the sapphire substrate is positioned at a top, so as to expose an upper surface of the third semiconductor layer; and

a step (g) of forming an electrode on the upper layer of the third semiconductor layer at a position above the first predetermined site.

Here, it is suitable to make the uppermost layer of the conductive layer, that is, the layer formed at a site that is in contact with the first semiconductor layer, be a reflective electrode. As the reflective electrode, Ag, an Ag-based metal (an alloy of Ni and Ag), Al, or the like can be used, for example. The light extraction efficiency can be increased by upward reflection of the light radiated downward (to the support substrate side) from the light-emitting layer.

At this time, the conductive oxide film layer is preferably a transparent electrode. The transparent electrode can be made, for example, of ITO (Indium Tin Oxide), IZO (Indium Zinc Oxide), In₂O₃, SnO₂, or the like. Since the conductive oxide film layer is made of a transparent electrode, the light radiated downward from the light-emitting layer can be made to reach the reflective electrode located below without great damping in the conductive oxide film layer, and further the reflected light coming from this reflective electrode can be guided upward at a high efficiency. In addition, since the layer is made of a conductive oxide film layer, the layer has a better thermal conductivity as compared with an insulating layer and is excellent in allowing the heat generated at the time of LED operation to escape, so that the element is suitable for increasing the lifetime.

The LED element having the above-described construction can be achieved by:

making the step (c) be a step of forming a transparent electrode as the conductive oxide film layer, and

making the step (d) have a step of forming a reflective electrode so as to cover an upper surface of the first semiconductor layer and an upper surface of the conductive oxide film layer, a step of forming a protective layer an upper surface of the reflective electrode, and a step of forming a solder layer an upper surface of the protective layer, and be a step of forming the conductive layer including the reflective electrode, the protective layer, and the solder layer.

Also, the LED element of the present invention may have another characteristic feature such that a Schottky barrier layer is formed at an interface between the conductive oxide film layer and the first semiconductor layer, in addition to the above-described characteristic features.

By adopting such a construction, the resistance value at a site where the conductive oxide film layer and the first semiconductor layer are in contact with each other can be further increased as compared with the resistance value at a site where the conductive layer (p-side conductive layer) and the first semiconductor layer are in contact with each other. This allows that, when a voltage is applied between the p-side conductive layer and the n-side electrode, the amount of a current flowing upward in the vertical direction from the conductive oxide film layer towards the n-side electrode can be further reduced. In other words, almost all of the current can be let to flow towards the n-side electrode via the light-emitting layer from the p-side conductive layer located at a position that does not face the n-side electrode in the vertical direction, so that the current flowing within the light-emitting layer can be further widened in the horizontal direction, thereby further increasing the light emission efficiency.

In particular, the path of a current flowing within the light-emitting layer at the time of voltage application is largely dependent on the resistance value between the high-concentration p-type first semiconductor layer and the layer (conductive layer or conductive oxide film layer) that is in contact with this layer. When the above construction is adopted, the resistance value in a contact region between the conductive oxide film layer and the first semiconductor layer can be considerably increased as compared with the resistance value in a contact region between the conductive layer and the first semiconductor layer.

The above-described effect can be obtained also by forming this Schottky barrier layer to have an extremely small thickness of, for example, about 3 to 5 nm. This thickness can be made to be a thickness approximately equal to the layer thickness of the high-concentration p-type first semiconductor layer.

The LED element having the above-described construction can be achieved by making the step (c) be a step of sputtering the material that forms the conductive oxide film layer, and forming a Schottky barrier layer at an interface between the first semiconductor layer and the conductive oxide film layer by the sputtering step. In other words, by this method, a Schottky barrier layer can be formed on the front surface of the first semiconductor layer along with forming the conductive oxide film layer.

Here, the effect of horizontal widening of the current flowing within the light-emitting layer can be obtained as long as the Schottky barrier layer is formed at an interface between the first semiconductor layer and the conductive oxide film layer. For this reason, it is possible to adopt a mode in which, in the step (c), ions are let to collide onto a target at a high energy only at the beginning of the sputtering step and thereafter, the ions are consecutively let to collide onto the target in a state in which the applied energy is reduced to be lower than the initial applied energy.

Also, in producing an LED element having a Schottky barrier layer, the LED element can be achieved by carrying out a step (h) of forming, after the step (b), a Schottky barrier layer by performing a reverse sputtering treatment on a front surface of the first semiconductor layer at the first predetermined site where it is planned to form the conductive oxide film layer, and thereafter carrying out the step (c).

Also, the LED element of the present invention may have another characteristic feature such that the support substrate and the conductive layer are formed to be wider in a horizontal direction than an LED layer including the first semiconductor layer, the second semiconductor layer, the light-emitting layer, and the third semiconductor layer, and

the LED element has an insulating layer formed at a position that protrudes in a horizontal direction from the LED layer so that a bottom surface of the insulating layer is in contact with an upper surface of the conductive oxide film layer or the conductive layer, in addition to the above-described characteristic features.

The LED element formed on a wafer is electrically separated from adjacent LED elements by passing, for example, through an element separation step after the above-described step (g). Specifically, the LED element is separated from the adjacent LED elements by etching an edge of the LED layer.

At this time, when a conductive oxide film layer is formed on the lower layer of the first semiconductor layer as described above, the conductive oxide film layer is also partly etched. This is because, although originally it is sufficient to finish the etching at the time point at which the upper surface of the conductive oxide film layer is exposed, it is in actual cases difficult. At this time, a part of the etched material of the conductive oxide film layer adheres onto the side surface of the LED layer, thereby possibly generating a leakage current or the like.

Therefore, while a conductive oxide film layer is formed on the lower layer of the first semiconductor layer at a position located vertically below the n-side electrode in the same manner as described above, an insulating layer is formed on the lower layer of the first semiconductor layer at a position located in a peripheral region outside the n-side electrode. When the edge of the LED layer is etched in this state in the element separation step, there is no fear of generating a leakage current as described above even when a part of the material adheres onto the side surface of the LED layer because the insulating layer is formed on the lower layer of the LED layer subject to etching. Also, the insulating layer can be let to function as an etching stopper, so that the etching can be easily finished at the time point at which the upper surface of the insulating layer is exposed.

The insulating layer may be either formed so that the bottom surface of the insulating layer is in contact with the upper surface of the conductive oxide film layer or formed so that the bottom surface of the insulating layer is in contact with the upper surface of the conductive layer.

The LED element having the above-described construction can be achieved by executing a step (i) of forming an insulating layer at a second predetermined site located at an edge of an upper layer of the first semiconductor layer after the step (b) and before the step (c), and executing a step (j) of etching the third semiconductor layer, the light-emitting layer, the second semiconductor layer, and the first semiconductor layer formed above the second predetermined site, so as to expose an upper surface of the insulating layer after the step (f) and before the step (g).

### Effect of the Invention

According to the present invention, there can be achieved an LED element that can prevent inviting a situation such as cracks or exfoliation at a layer interface at the time of production while ensuring horizontal-direction widening of a current flowing within a light-emitting layer.

### BRIEF DESCRIPTION OF THE DRAWINGS

FIG. 1 is a schematic sectional view of an LED element.

FIG. 2A is a table showing presence or absence of film exfoliation when LED elements are produced using different materials.

FIG. 2B show top surface photographs of wafers on which LED elements are arranged when the LED elements are produced using different materials.

FIG. 3A is another schematic sectional view of an LED element.

FIG. 3B is another schematic sectional view of an LED element.

FIG. 3C is another schematic sectional view of an LED element.

FIG. 3D is another schematic sectional view of an LED element.

FIG. 4A is a part of a process sectional view of an LED element.

FIG. 4B is a part of a process sectional view of an LED element.

FIG. 4C is a part of a process sectional view of an LED element.

FIG. 4D is a part of a process sectional view of an LED element.

FIG. 4E is a part of a process sectional view of an LED element.

FIG. 4F is a part of a process sectional view of an LED element.

FIG. 4G is a part of a process sectional view of an LED element.

FIG. 4H is a part of a process sectional view of an LED element.

FIG. 4I is a part of a process sectional view of an LED element.

FIG. 4J is a part of a process sectional view of an LED element.

FIG. 4K is a part of a process sectional view of an LED element.

FIG. 4L is a part of a process sectional view of an LED element.

FIG. 4M is a part of a process sectional view of an LED element.

FIG. 5 is a flowchart showing a method for producing an LED element.

### MODE FOR CARRYING OUT THE INVENTION

An LED element of the present invention and a production method therefor will be described with reference to the drawings. Here, in each drawing, the dimensional ratio of the drawings does not necessarily coincide with the actual dimensional ratio.

### [Structure]

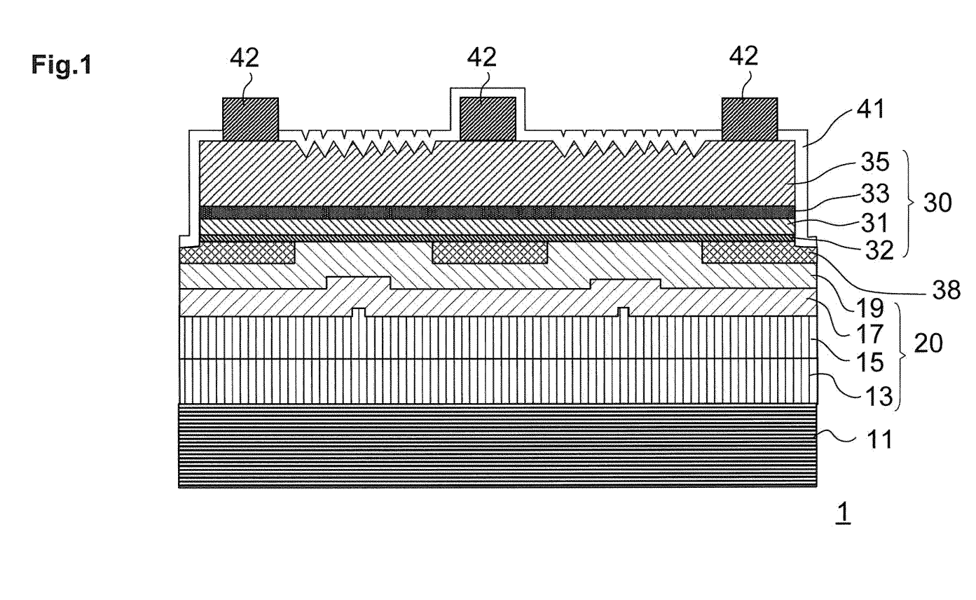

A structure of an LED element 1 of the present invention will be described with reference to FIG. 1. FIG. 1 is a schematic sectional view of the LED element 1.

The LED element 1 is constructed to include a support substrate 11, a conductive layer 20, a conductive oxide film layer 38, an LED layer 30, and an electrode 42. The LED layer 30 is formed in such a manner that a p-type semiconductor layer 32 (corresponding to a “first semiconductor layer”) having a high concentration, a p-type semiconductor layer 31 (corresponding to a “second semiconductor layer”) having a lower concentration than that of the p-type semiconductor layer 32, a light-emitting layer 33, and an n-type semiconductor layer 35 (corresponding to a “third semiconductor layer”) are laminated in this order from below.

### (Support Substrate 11)

The support substrate 11 is made of a conductive substrate such as CuW, W, or Mo, or a semiconductor substrate such as Si.

### (Conductive Layer 20)

A conductive layer 20 made of a multi-layered structure is formed on the upper layer of the support substrate 11. In the present embodiment, this conductive layer 20 includes a solder layer 13, a solder layer 15, a protective layer 17, and a reflective electrode 19.

The solder layer 13 and the solder layer 15 are made, for example, of Au—Sn, Au—In, Au—Cu—Sn, Cu—Sn, Pd—Sn, Sn, or the like. As will be described later, these solder layer 13 and solder layer 15 are formed by bonding the two with each other after the solder layer 13 formed on the support substrate 11 and the solder layer 15 formed on another substrate are placed to face each other.

The protective layer 17 is made, for example, of a Pt-based metal (an alloy of Ti and Pt), W, Mo, or the like. As will be described later, in bonding via the solder layers, the protective layer 17 functions to prevent decrease in the light emission efficiency caused by diffusion of the material constituting the solder to the reflective electrode 19 side described later to decrease the reflectivity.

The reflective electrode 19 is made, for example, of an Ag-based metal (an alloy of Ni and Ag), Al, Rh, or the like. It is assumed in the LED element 1 that the light radiated from the light-emitting layer 33 of the LED layer 30 is extracted in the upward direction of FIG. 1, and the reflective electrode 19 functions to enhance the light emission efficiency by reflecting the light radiated downward from the light-emitting layer 33 in the upward direction.

The conductive layer 20 is partially in contact with the LED layer 30, more particularly the p-type semiconductor layer 32 having a high concentration and, when a voltage is applied between the support substrate 11 and the electrode 42, a current path in which the current flows to the electrode 42 via the support substrate 11, the conductive layer 20, and the LED layer 30 is formed.

### (Conductive Oxide Film Layer 38)

The conductive oxide film layer 38 is made, for example, of an oxide conductive material such as ITO, IZO, In₂O₃, SnO₂, or IGZO (InGaZnOx). An upper surface of this conductive oxide film layer 38 is in contact with a bottom surface of the p-type semiconductor layer 32. The function of this conductive oxide film layer 38 will be described later. Here, as this conductive oxide film layer 38, a light-permeable oxide conductive material is more preferably used.

### (LED Layer 30)

As described above, the LED layer 30 is formed in such a manner that the p-type semiconductor layer 32 having a high concentration, the p-type semiconductor layer 31 having a low concentration, the light-emitting layer 33, and the n-type semiconductor layer 35 are laminated in this order from below.

The p-type semiconductor layer 32 is made, for example, of GaN. Also, the p-type semiconductor layer 31 is made, for example, of AlₘGa₁₋ₘN (0≦m<1). Each of the layers is doped with a p-type impurity such as Mg, Be, Zn, or C.

The light-emitting layer 33 is made, for example, of a semiconductor layer having a multiquantum well structure formed by repetition of a well layer made of GaInN and a barrier layer made of AlGaN. These layers may be either non-doped or doped to be p-type or n-type.

The n-type semiconductor layer 35 is made, for example, of a multi-layered structure including a layer (electron supply layer) made of AlₙGa₁₋ₘN (0≦n<1) and a layer (protective layer) made of GaN. At least the protective layer is doped with an n-type impurity such as Si, Ge, S, Se, Sn, or Te and, in particular, is preferably doped with Si.

An undulation is formed on an upper surface of the n-type semiconductor layer 35. This is made for the purpose of increasing the amount of light extracted to the outside of the element by reducing the light amount by which the light radiated upward from the light-emitting layer (and the reflected light that is radiated upward from the reflective electrode 19) is reflected downward at the front surface of the n-type semiconductor layer 35.

### (Electrode 42, Insulating Layer 41)

The electrode 42 is formed on the upper layer of the n-type semiconductor layer 35 and is made of an n-type electrode made, for example, of Cr—Au. In particular, in the LED element 1, the electrode 42 is formed on the upper layer of the n-type semiconductor layer 35 at a position facing the conductive oxide film layer 38 in the vertical direction.

To the electrode formed at an edge among the electrodes 42, a wire formed, for example, of Au, Cu, or the like is connected (not illustrated in the drawings), and the other end of this wire is connected to a power supply pattern of a substrate on which the LED element 1 is disposed (not illustrated in the drawings).

The insulating layer 41 is made, for example, of SiO₂, SiN, Zr₂O₃, AlN, Al₂O₃, or the like and is formed on the upper surface and the side surface of the LED layer 30 and in the peripheries of the electrodes 42 to which the wire is not connected. The insulating layer 41 functions as a protective film for protecting the surfaces of the LED layer 30 and the electrodes 42.

### [Function of Conductive Oxide Film Layer 38]

Next, a function of the conductive oxide film layer 38 included in the LED element 1 will be described. The conductive oxide film layer 38 is disposed for the purpose of enlarging the light emission region of the LED layer 30 without causing a problem of film exfoliation at the time of processing.

First, a case in which the conductive oxide film layer 38 is not formed is assumed. At this time, the p-type semiconductor layer 32 and the reflective electrode 19 are in contact with each other at a position facing the electrode 42 in the vertical direction. When a voltage is applied between the reflective electrode 19 and the electrode 42 under this construction, a current path in which the current flows almost by the shortest distance from the reflective electrode 19 towards the electrode 42 is formed, as described in the background art section. As a result of this, flow of a current in the LED layer 30 is concentrated in a region facing the electrode 42, whereby the light-emitting layer 33 in that region emits light in a concentrated manner, and light emission of the light-emitting layer 33 at other sites becomes weak. Therefore, the light-emitting layer 33 emits light in a restricted manner in the region sandwiched between the reflective electrode 19 and the electrode 42 in the vertical direction, and the amount of light extracted from the LED element becomes extremely small.

In contrast, referring to FIG. 1, the LED element 1 has a conductive oxide film layer 38 formed on the lower layer of the p-type semiconductor layer 32 at a position facing the electrode 42 in the vertical direction. Although having a smaller specific resistance as compared with an insulating layer such as SiO₂, the conductive oxide film layer 38 can be made to have a specific resistance of about hundred times as large as that of the reflective electrode 19 made of Ag or the like. While the reflective electrode 19 is in contact with the p-type semiconductor layer 32 at a position that does not face the electrode 42 in the vertical direction, the reflective electrode 19 is in contact with the conductive oxide film layer 38 at a position facing the electrode 42 in the vertical direction and is not in contact with the p-type semiconductor layer 32.

Therefore, when a voltage is applied between the reflective electrode 19 and the electrode 42, a current flows along a current path that goes towards the electrode 42 via the light-emitting layer 33 from the reflective electrode 19 at a site that is in contact with the p-type semiconductor layer 32, which is not located vertically below the electrode 42. Therefore, the current can be made to flow via a current path having a certain width in the horizontal direction in the light-emitting layer 33. This allows that the region where the current flows in the light-emitting layer 33 is widened in the horizontal direction, whereby high light emission efficiency is achieved in the LED element 1.

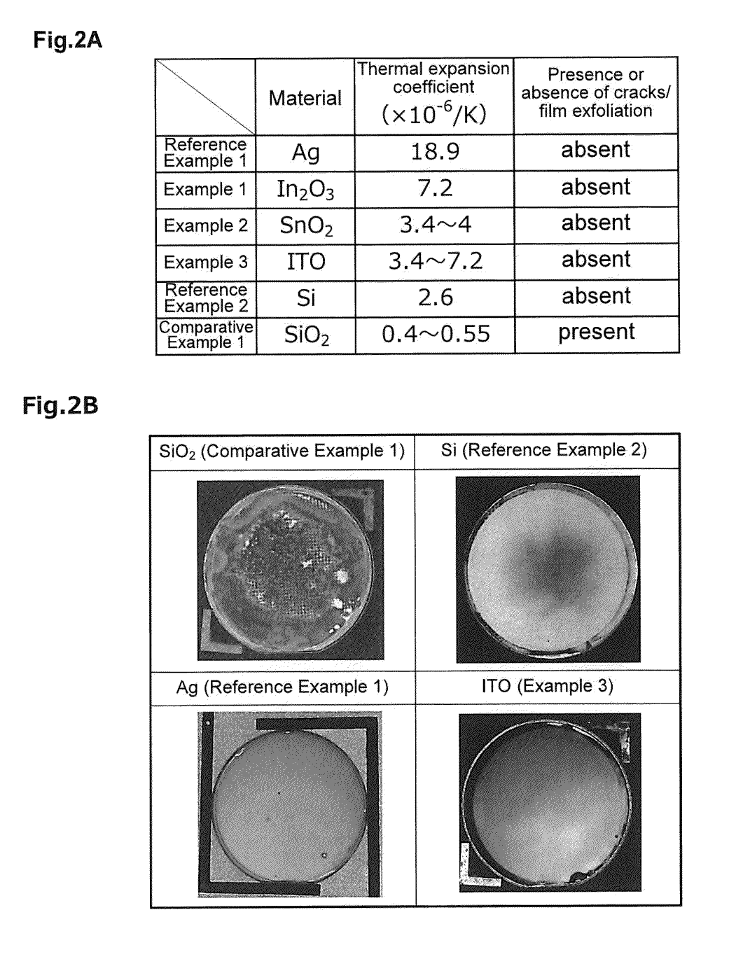

Next, the effect of preventing film exfoliation will be described with reference to FIGS. 2A and 2B. FIG. 2A is a table showing presence or absence of film exfoliation when the LED elements are produced using different materials for forming a film at a site of the conductive oxide film layer 38 shown in FIG. 1, and FIG. 2B shows top surface photographs of wafers before element separation when the respective materials are used. The photograph of FIG. 2B was taken by using a SAT (Scanning Acoustic Tomograph).

Here, in the table shown in FIG. 2A, the materials are arranged in the descending order of the thermal expansion coefficient from the top.

Example 1 corresponds to a case in which the LED element 1 is produced using In₂O₃ as the conductive oxide film layer 38. Similarly, Example 2 corresponds to a case in which the LED element 1 is produced using SnO₂ as the conductive oxide film layer 38, and Example 3 corresponds to a case in which the LED element 1 is produced using ITO.

On the other hand, Comparative Example 1 corresponds to a case in which the LED element 1 is produced by forming SiO₂ at a site of the conductive oxide film layer 38 shown in FIG. 1. This Comparative Example 1 assumes an LED element having a conventional construction in which an insulating layer is formed at a position facing the electrode 42 so that a current may flow in a horizontally wide region within the light-emitting layer 33.

Also, Reference Example 1 corresponds to a construction in which Ag of the same kind as the reflective electrode 19 is formed at a site of the conductive oxide film layer 38 shown in FIG. 1. This Reference Example 1 assumes an LED element having a conventional construction in which a treatment for letting the current flow in a horizontally wide region within the light-emitting layer 33 is not carried out.

Also, Reference Example 2 corresponds to a construction in which Si is formed at a site of the conductive oxide film layer 38 shown in FIG. 1. This Reference Example 2 is an LED element formed for examining the relationship between the thermal expansion coefficient and the presence or absence of cracks or exfoliation at the interface to the reflective electrode 38 by forming a material exhibiting a thermal expansion coefficient lower than that of ITO and higher than that of SiO₂ at the same site.

In FIG. 2B, photographs are shown for four patterns including ITO (Example 3), SiO₂ (Comparative Example 1), Ag (Reference Example 1), and Si (Reference Example 2). According to FIG. 2B, an image of an internal structure such as a circuit pattern is depicted in the photograph of Comparative Example 1, suggesting that voids are formed in the inside. In contrast, in none of the photographs of Reference Example 1, Reference Example 2, and Example 3, such images as depicted in Comparative Example 1 are seen, and it will be understood that no voids are formed in the inside.

In other words, while cracks or film exfoliation is generated at the interface in the case of Comparative Example 1, no cracks or film exfoliation is generated at the interface in the case of Reference Example 1, Reference Example 2, and Example 3. Here, although not shown in FIG. 2B, photographs similar to those of Example 3 have been obtained also in Example 1 and Example 2, and it will be understood that no exfoliation is generated in these cases also.

As described above, Reference Example 1 assumes an LED element having a conventional construction in which a treatment for letting the current flow in a horizontally wide region within the light-emitting layer 33 is not carried out. On the other hand, Comparative Example 1 assumes an LED element having another conventional construction in which the above-described treatment is carried out by forming a film of SiO₂ at the site of the conductive oxide film layer 38 shown in FIG. 1. Although no cracks or film exfoliation has been confirmed in Reference Example 1, cracks or film exfoliation has been confirmed in Comparative Example 1. From this, it will be understood that SiO₂ formed as a film at the site of the conductive oxide film layer 38 shown in FIG. 1 gives rise to cracks or film exfoliation. Since SiO₂ has an excellent close adhesion property to semiconductor layers, it is suggested that cracks or film exfoliation is generated at the interface to the reflective electrode 19 (Ag) of the lower surface and not at the interface to the p-type semiconductor layer 32 of the upper surface.

In Reference Example 2 in which a film of Si has been formed at the site of the conductive oxide film layer 38, cracks or film exfoliation has not been confirmed. Also, in none of Examples 1 to 3, cracks or film exfoliation has been confirmed.

Here, the thermal expansion coefficient differs by a multiple of about 50 times between Ag constituting the reflective electrode 19 and SiO₂. For this reason, when the element is heated at the time of production, the reflective electrode 19 thermally expands largely, whereas SiO₂ does not expand so much as compared with the reflective electrode 19. For this reason, when the element is cooled after the heating treatment, the thermally expanded reflective electrode 19 shrinks largely, whereas SiO₂ shrinks little as compared with the reflective electrode 19, so that a stress seems to be generated at the interface of these to generate cracks or film exfoliation. In other words, it will be understood that problems such as cracks or film exfoliation at the interface are generated when a material having a large difference in thermal expansion coefficient to the material (here, Ag) constituting the reflective electrode 19 is formed on the upper layer of the reflective electrode 19.

Considering the above, the conductive oxide film layer 38 is preferably made of a material having a thermal expansion coefficient of 1×10⁻⁶/K or more and 1×10⁻⁵/K or less, and is more preferably made of a material having a thermal expansion coefficient of 3×10⁻⁶/K or more and 8×10⁻⁶/K or less. Further, the conductive oxide film layer 38 is more preferably made of a conductive oxide film material having light permeability and having a relatively large specific resistance, and examples of this include ITO, IZO, In₂O₃, and SnO₂ described above.

### [Different Constructions]

Hereafter, different constructions of the LED element 1 will be described.

### (Different Construction 1)

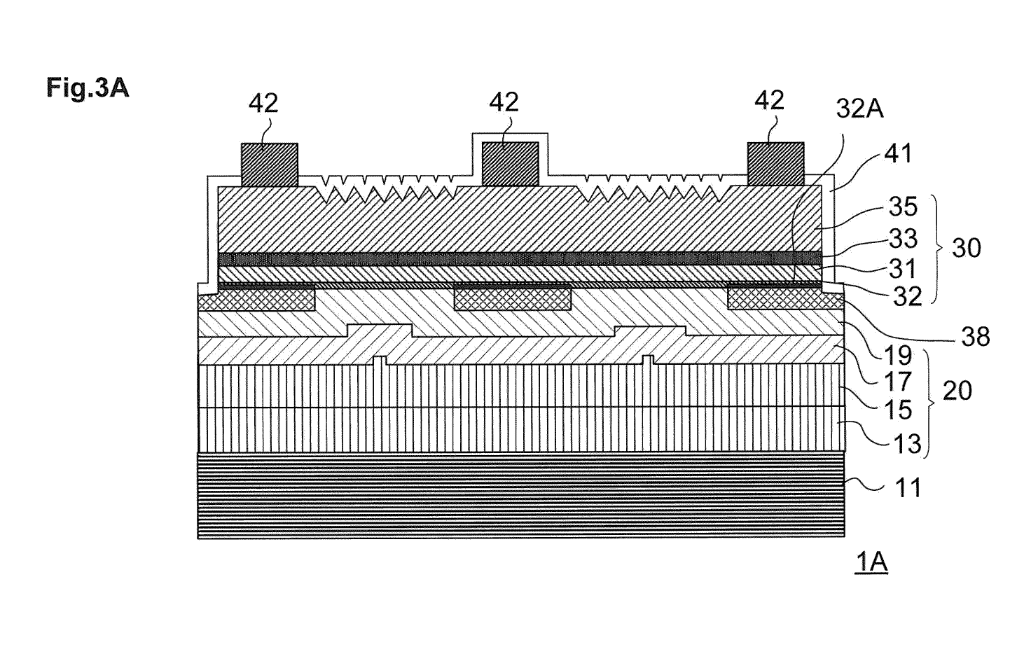

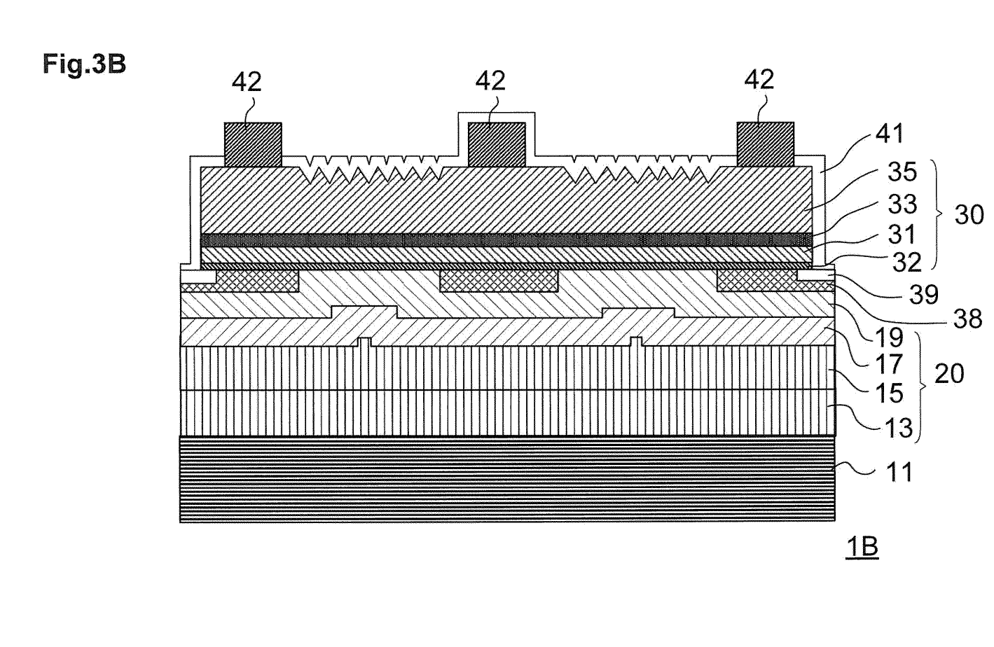

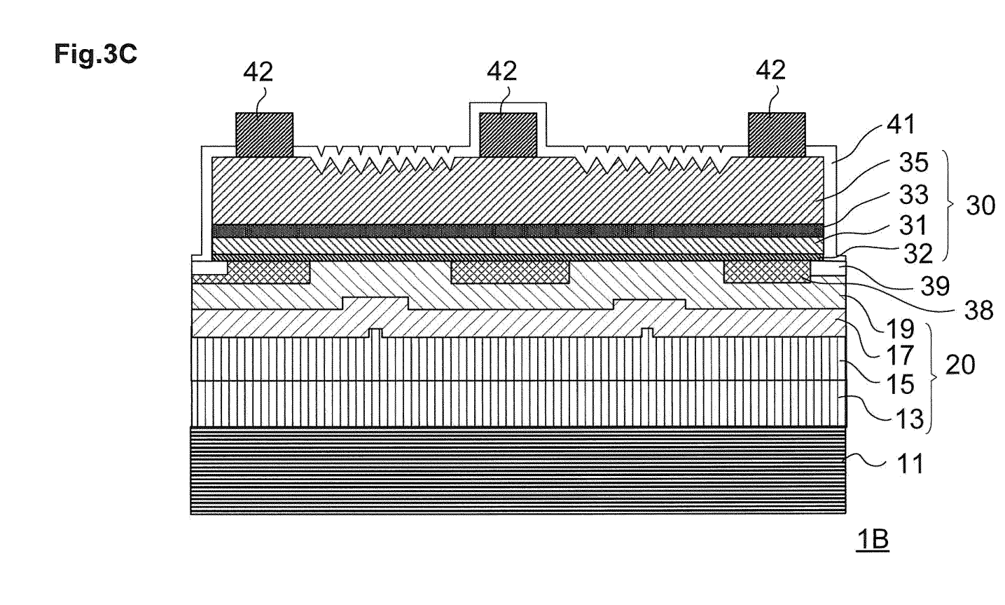

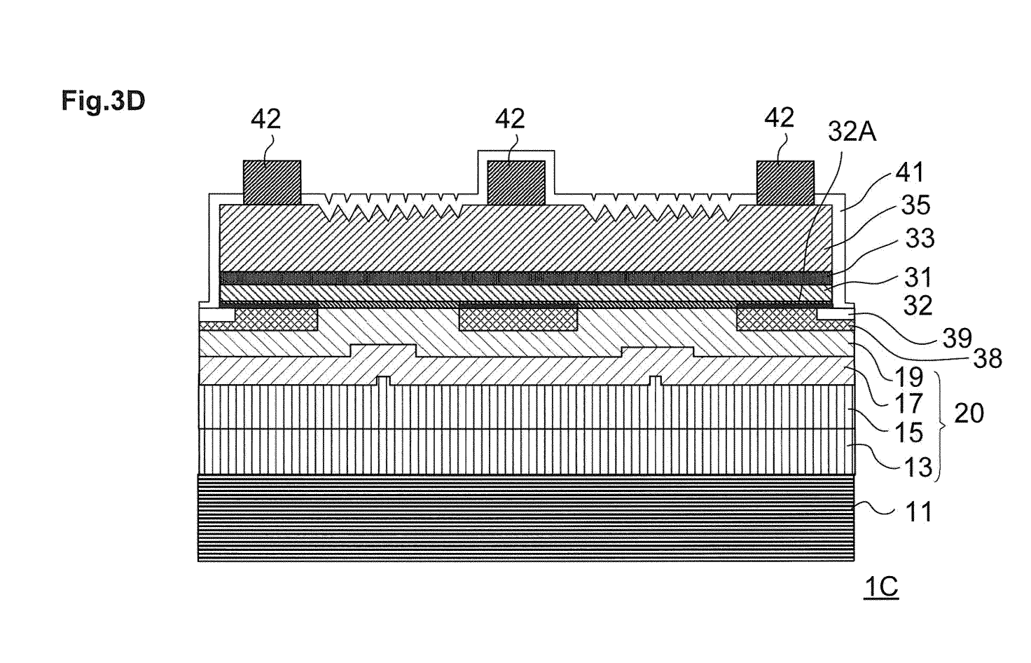

FIG. 3A is another schematic sectional view of the present element. As compared with the LED element 1 shown in FIG. 1, the LED element 1A shown in FIG. 3A is different in that a Schottky barrier layer 32A is formed at the interface between the conductive oxide film layer 38 and the p-type semiconductor layer 32.

This Schottky barrier layer 32A forms a region having a large resistance, and the thickness thereof is extremely small. When such a Schottky barrier layer 32A is formed at the interface between the p-type semiconductor layer 32 and the conductive oxide film layer 38, the resistance value between the reflective electrode 19 and the p-type semiconductor layer 32 at a position vertically below the electrode 42 can be further increased. Therefore, the resistance value between the two at a site that is not located at a position vertically below the electrode 42, that is, at a site where the reflective electrode 19 and the p-type semiconductor layer 32 are in contact with each other, becomes extremely smaller than the resistance value between the two at a position vertically below the electrode 42.

As a result of this, when a voltage is applied between the reflective electrode 19 and the electrode 42, the amount of a current that flows vertically upward from the reflective electrode 19 located at a position facing the electrode 42 in the vertical direction towards the electrode 42 becomes further smaller, so that almost all of the current can be let to flow from the reflective electrode 19 located at a position that does not face the electrode 42 in the vertical direction towards the electrode 42. Therefore, the horizontal widening of the current within the light-emitting layer 33 is further achieved, thereby further increasing the light emission efficiency.

### (Different Construction 2)

FIG. 3B is another schematic sectional view of the present element. As compared with the LED element 1 shown in FIG. 1, the LED element 1B shown in FIG. 3B is different in that an insulating layer 39 is disposed on the lower layer of the insulating layer 41.

The insulating layer 41 is formed on the upper surface and the side surface of the LED layer 30, and functions as a protective film for protecting the LED layer 30. As will be described later, this insulating layer 41 is formed as a film after the LED layer 30 is etched so as to be separated from adjacent LED elements.

At this time, when a conductive oxide film layer 38 is formed on the lower layer of the p-type semiconductor layer 32 as in the LED element 1 shown in FIG. 1, the conductive oxide film layer 38 is also partly etched. This is because, although originally it is sufficient for performing element separation to finish the etching at the time point at which the upper surface of the conductive oxide film layer 38 is exposed, it is in actual cases difficult. At this time, a part of the etched material of the conductive oxide film layer 38 adheres onto the side surface of the LED layer 30, thereby possibly generating a leakage current or the like. When such a phenomenon occurs, the breakdown voltage decreases, thereby inviting an inconvenience such as degradation of the electric properties.

In contrast, adopting the construction of the LED element 1B shown in FIG. 3B allows that, when the edge of the LED layer 30 is etched in the element separation step, there is no fear of generating a leakage current as described above even when a part of the material adheres onto the side surface of the LED layer 30 because the insulating layer 39 is formed on the lower layer of the LED layer 30 subject to etching.

Here, the LED element 1B shown in FIG. 3B has a construction such that the insulating layer 39 is formed on the upper surface of the conductive oxide film layer 38; however, the insulating layer 39 may be formed on the upper surface of the conductive layer 20 (See FIG. 3C).

Also, it is possible to adopt a construction in which a Schottky barrier layer 32A is further provided as in the LED element 1C shown in FIG. 3D (See FIG. 3D).

### [Method for Producing LED Element 1]

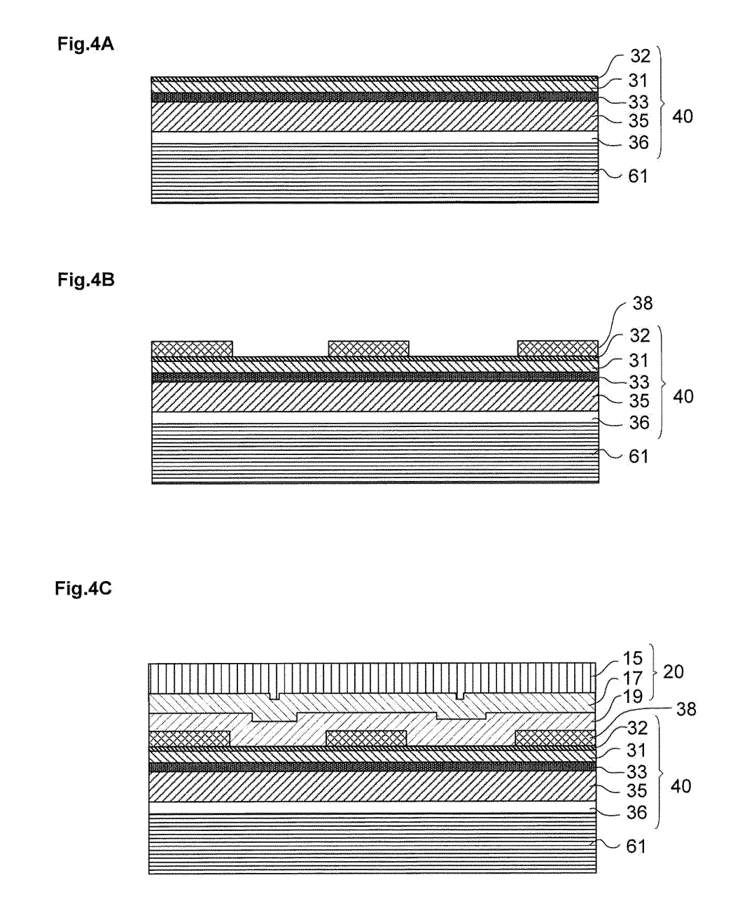

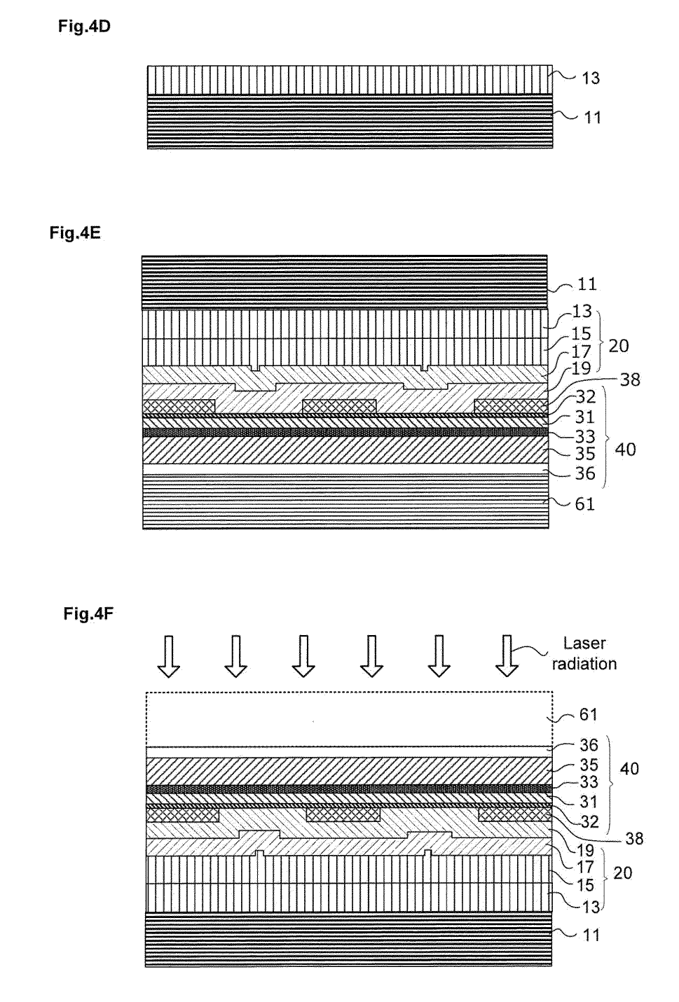

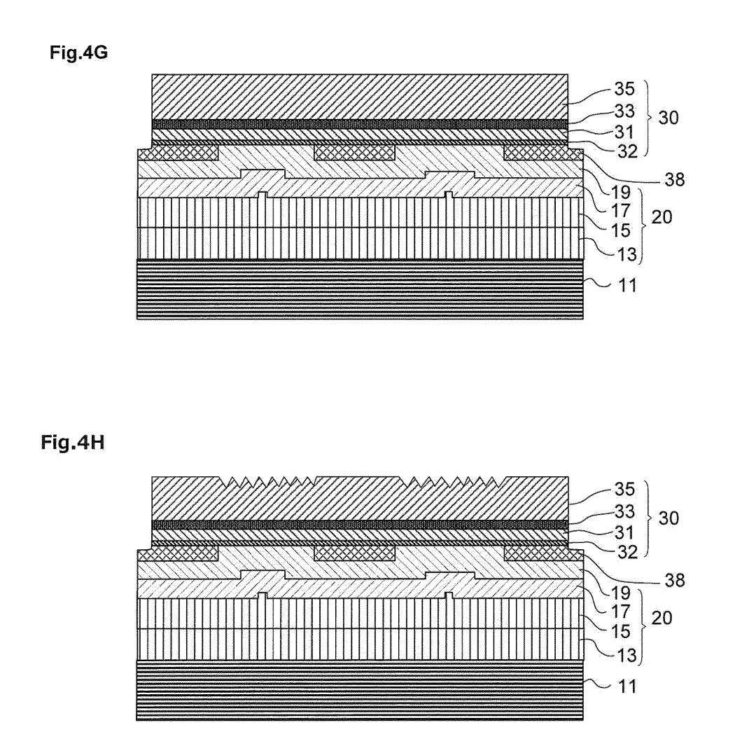

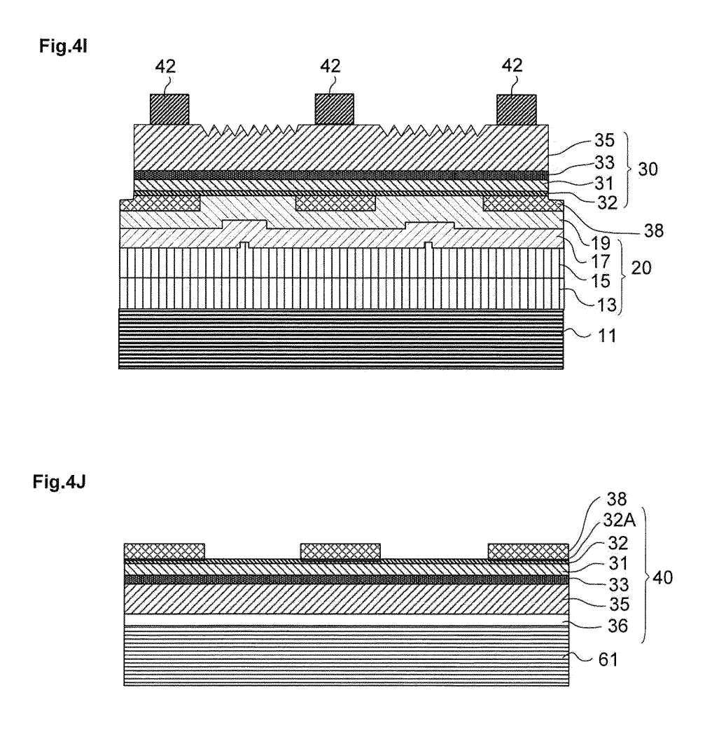

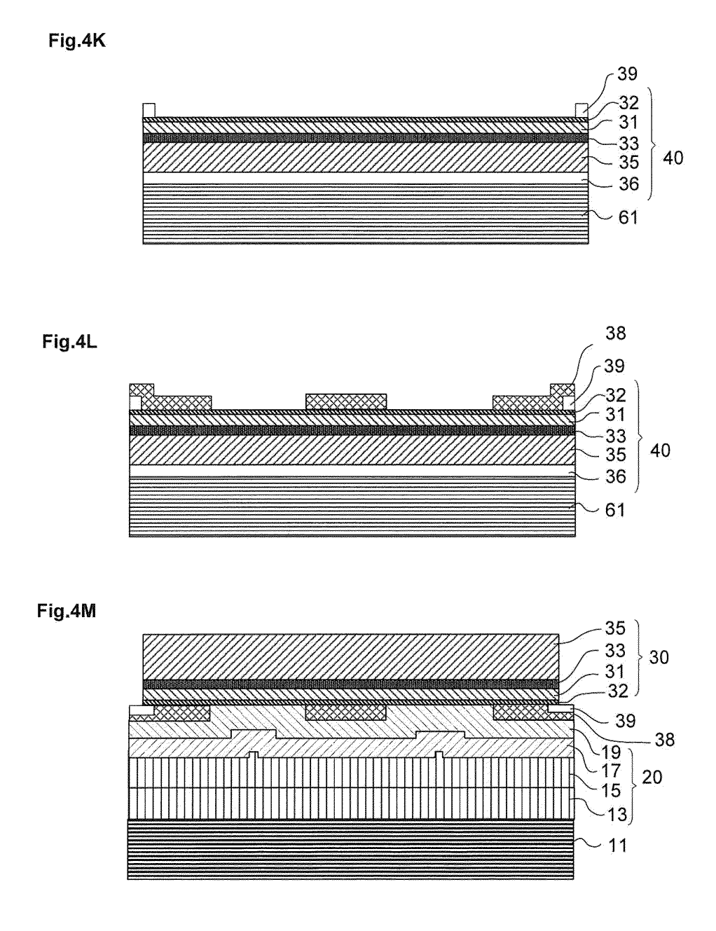

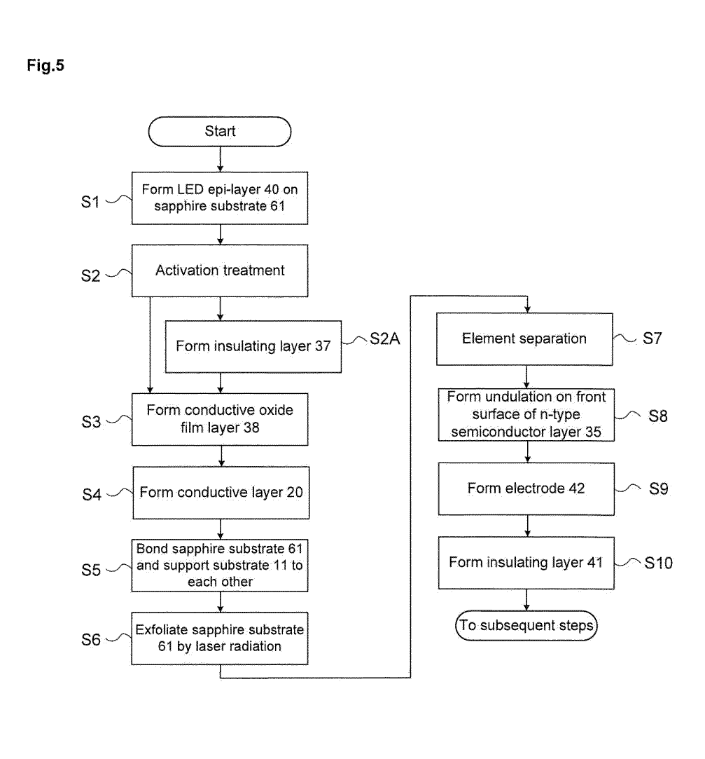

Next, a method for producing the LED element 1 of the present invention will be described with reference to the process sectional views shown in FIGS. 4A to 4M and the flowchart shown in FIG. 5. Also, the step number shown in the following description corresponds to the step number in the flowchart of FIG. 5. Here, methods for producing the LED elements 1A and 1B will be described later.

Also, the production conditions, the dimensions such as the film thickness, and the like described in the following production method are merely examples, and the present invention is not limited to these numerical values alone.

### (Step S1)

Referring to FIG. 4A, an LED epi-layer 40 is formed on a sapphire substrate 61. This step S1 corresponds to the step (a) and the step (b) and is carried out, for example, according to the following procedure.

### <Preparation of Sapphire Substrate 61>

First, a c-plane sapphire substrate 61 is cleaned. More specifically, this cleaning is carried out, for example, by placing the c-plane sapphire substrate 61 in a treatment furnace of an MOCVD (Metal Organic Chemical Vapor Deposition) apparatus and raising the temperature within the furnace to, for example, 1150° C. while allowing a hydrogen gas having a flow rate of 10 slm to flow within the treatment furnace. This step of preparing the sapphire substrate 61 corresponds to the step (a).

### <Formation of Non-Doped Layer 36>

Next, on a front surface of the c-plane sapphire substrate 61, a low-temperature buffer layer made of GaN is formed, and further a foundation layer made of GaN is formed thereon. These low-temperature buffer layer and foundation layer correspond to the non-doped layer 36.

A more specific method for forming the non-doped layer 36 is, for example, as follows. First, the pressure within the furnace of the MOCVD apparatus is set to be 100 kPa, and the temperature within the furnace is set to be 480° C. Then, while allowing a nitrogen gas and a hydrogen gas each having a flow rate of 5 slm to flow as a carrier gas within the treatment furnace, trimethylgallium having a flow rate of 50 μmol/min and ammonia having a flow rate of 250000 μmol/min are supplied for 68 seconds as a source material gas into the treatment furnace. This allows that a low-temperature buffer layer made of GaN having a thickness of 20 nm is formed on the front surface 61 of the c-plane sapphire substrate.

Next, the temperature within the furnace of the MOCVD apparatus is raised to 1150° C. Then, while allowing a nitrogen gas having a flow rate of 20 slm and a hydrogen gas having a flow rate of 15 slm to flow as a carrier gas within the treatment furnace, trimethylgallium having a flow rate of 100 μmol/min and ammonia having a flow rate of 250000 μmol/min are supplied for 30 minutes as a source material gas into the treatment furnace. This allows that a foundation layer made of GaN having a thickness of 1.7 μm is formed on the front surface of the first buffer layer.

<Formation of n-Type Semiconductor Layer 35>

Next, an electron supply layer having a composition of AlₙGa₁₋ₙN (0≦n<1) is formed on the upper layer of the non-doped layer 36, and further a protective layer made of n-type GaN is formed thereon. These electron supply layer and protective layer correspond to the n-type semiconductor layer 35.

Amore specific method for forming the n-type semiconductor layer 35 is, for example, as follows. First, the pressure within the furnace of the MOCVD apparatus is set to be 30 kPa. Then, while allowing a nitrogen gas having a flow rate of 20 slm and a hydrogen gas having a flow rate of 15 slm to flow as a carrier gas within the treatment furnace, trimethylgallium having a flow rate of 94 μmol/min, trimethylaluminum having a flow rate of 6 μmol/min, ammonia having a flow rate of 250000 μmol/min, and tetraethylsilane having a flow rate of 0.025 μmol/min are supplied for 30 minutes as a source material gas into the treatment furnace. This allows that an electron supply layer having a composition of Al_{0.06}Ga_{0.94}N, having an Si concentration of 1×10¹⁹/cm³, and having a thickness of 1.7 μm is formed on the upper layer of the non-doped layer 36.

Thereafter, supply of trimethylaluminum is stopped, and the source material gas other than that is supplied for 6 seconds, thereby to form a protective layer made of n-type GaN having a thickness of 5 nm on the upper layer of the electron supply layer.

Here, as the n-type impurity contained in the n-type semiconductor layer 35, silicon (Si), germanium (Ge), sulfur (S), selenium (Se), tin (Sn), tellurium (Te), and the like can be used. Among these, silicon (Si) is particularly preferable.

### <Formation of Light-Emitting Layer 33>

Next, a light-emitting layer 33 having a multiquantum well structure in which a well layer made of GaInN and a barrier layer made of n-type AlGaN are periodically repeated is formed on the upper layer of the n-type semiconductor layer 35.

A more specific method for forming the light-emitting layer 33 is, for example, as follows. First, the pressure within the furnace of the MOCVD apparatus is set to be 100 kPa, and the temperature within the furnace is set to be 830° C. Then, while allowing a nitrogen gas having a flow rate of 15 slm and a hydrogen gas having a flow rate of 1 slm to flow as a carrier gas within the treatment furnace, a step of supplying trimethylgallium having a flow rate of 10 μmol/min, trimethylindium having a flow rate of 12 μmol/min, and ammonia having a flow rate of 300000 μmol/min for 48 seconds as a source material gas into the treatment furnace is carried out. Thereafter, a step of supplying trimethylgallium having a flow rate of 10 μmol/min, trimethylaluminum having a flow rate of 1.6 μmol/min, tetraethylsilane having a flow rate of 0.002 μmol/min, and ammonia having a flow rate of 300000 μmol/min for 120 seconds into the treatment furnace is carried out. Subsequently, by repeating these two steps, a light-emitting layer 33 having a multiquantum well structure with 15 periods constructed by a well layer made of GaInN having a thickness of 2 nm and a barrier layer made of n-type AlGaN having a thickness of 7 nm is formed on the front surface of the n-type semiconductor layer 35.

<Formation of p-Type Semiconductor Layer 31 and p-Type Semiconductor Layer 32>

Next, a p-type semiconductor layer 31 made of AlₘGa₁₋ₘN (0≦m<1) is formed on the upper layer of the light-emitting layer 33, and further a p-type semiconductor layer 32 having a high concentration is formed thereon. The p-type semiconductor layer 32 corresponds to a contact layer.

A more specific method for forming the p-type semiconductor layer 31 and the p-type semiconductor layer 32 is, for example, as follows. First, the pressure within the furnace of the MOCVD apparatus is maintained to be 100 kPa and, while allowing a nitrogen gas having a flow rate of 15 slm and a hydrogen gas having a flow rate of 25 slm to flow as a carrier gas within the treatment furnace, the temperature within the furnace is raised to 1050° C. Thereafter, trimethylgallium having a flow rate of 35 μmol/min, trimethylaluminum having a flow rate of 20 μmol/min, ammonia having a flow rate of 250000 μmol/min, and bis(cyclopentadienyl)magnesium having a flow rate of 0.1 μmol/min are supplied for 60 seconds as a source material gas into the treatment furnace. This allows that a hole supply layer having a composition of Al_{0.3}Ga_{0.7}N and having a thickness of 20 nm is formed on the front surface of the light-emitting layer 33. Thereafter, by supplying the source material gas for 360 seconds after changing the flow rate of trimethylaluminum to 9 μmol/min, a hole supply layer having a composition of Al_{0.13}Ga_{0.87}N and having a thickness of 120 nm is formed. By these hole supply layers, the p-type semiconductor layer 31 is formed.

Further thereafter, supply of trimethylaluminum is stopped, and the source material gas is supplied for 20 seconds after changing the flow rate of bis(cyclopentadienyl)magnesium to 0.2 μmol/min. This allows that the p-type semiconductor layer 32 made of p-type GaN having a thickness of 5 nm is formed.

Here, as the p-type impurity, magnesium (Mg), beryllium (Be), zinc (Zn), carbon (C), and the like can be used.

In this manner, the LED epi-layer 40 made of the non-doped layer 36, the n-type semiconductor layer 35, the light-emitting layer 33, the p-type semiconductor layer 31, and the (high-concentration) p-type semiconductor layer 32 is formed on the upper layer of the sapphire substrate 61.

### (Step S2)

Next, an activation treatment is carried out on the wafer obtained in the step S1. More specifically, an activation treatment at 650° C. for 15 minutes is carried out in a nitrogen atmosphere using an RTA (Rapid Thermal Anneal) apparatus.

### (Step S3)

Next, referring to FIG. 4B, a conductive oxide film layer 38 is formed at a predetermined site (first predetermined site) of an upper layer of the p-type semiconductor layer 32. More specifically, after the upper layer of the p-type semiconductor layer 32 in a region where the conductive oxide film layer 38 is not to be formed is masked in advance, a film of an oxide conductive light-permeable material such as ITO or IZO is formed to 200 nm by the sputtering method.

Here, as the oxide conductive light-permeable material formed into a film, a material having a thermal expansion coefficient of 1×10⁻⁶/K or more and 1×10⁻⁵/K or less is used.

More preferably, a material having a thermal expansion coefficient of 3×10⁻⁶/K or more and 8×10⁻⁶/K or less is used.

This step S3 corresponds to the step (c).

### (Step S4)

Referring to FIG. 4C, a conductive layer 20 is formed to cover the upper surface of the p-type semiconductor layer 32 and the conductive oxide film layer 38. Here, the conductive layer 20 having a multi-layered structure including a reflective electrode 19, a protective layer 17, and a solder layer 15 is formed.

A more specific method for forming the conductive layer 20 is, for example, as follows. First, a film of Ni having a thickness of 0.7 nm and a film of Ag having a thickness of 120 nm are formed over the whole surface so as to cover the upper surface of the p-type semiconductor layer 32 and the conductive oxide film layer 38 by using a sputtering apparatus, thereby to form the reflective electrode 19. Next, contact annealing at 400° C. for 2 minutes is carried out in a dry air atmosphere using an RTA apparatus.

Next, a film of Ti having a thickness of 100 nm and a film of Pt having a thickness of 200 nm are formed for 3 periods on the upper surface (Ag surface) of the reflective electrode 19 using an electron beam vapor deposition apparatus (EB apparatus), thereby to form the protective layer 17. Further thereafter, Ti having a thickness of 10 nm is vapor-deposited on the upper surface (Pt surface) of the protective layer 17, and thereafter Au—Sn solder made of 80% of Au and 20% of Sn is vapor-deposited in a thickness of 3 μm, thereby to form the solder layer 15.

Here, in this step of forming the solder layer 15, a solder layer 13 may be formed on an upper surface of a support substrate 11 that is prepared separately from the sapphire substrate 61 (See FIG. 4D). This solder layer 13 may be made of the same material as the solder layer 15. By joining the solder layer 15 and the solder layer 13 with each other in the next step, the sapphire substrate 61 and the support substrate 11 are bonded to each other. Here, as described above in the section of structure, CuW, for example, is used as this support substrate 11.

This step S4 corresponds to the step (d).

### (Step S5)

Next, referring to FIG. 4E, the sapphire substrate 61 and the support substrate 11 are bonded to each other. More specifically, the solder layer 15 and the solder layer 13 formed on the upper layer of the support substrate 11 are bonded to each other at a temperature of 280° C. and under a pressure of 0.2 MPa. This step S5 corresponds to the step (e).

### (Step S6)

Next, referring to FIG. 4F, the sapphire substrate 61 is exfoliated. More specifically, KrF excimer laser is radiated from the sapphire substrate 61 side in a state in which the sapphire substrate 61 is facing upward and the support substrate 11 is facing downward, so as to exfoliate the sapphire substrate 61 by decomposing the interface between the sapphire substrate 61 and the LED epi-layer 40. While laser passes through the sapphire substrate 61, GaN located therebelow absorbs laser, so that this interface comes to have a high temperature to decompose GaN. This exfoliates the sapphire substrate 61.

Thereafter, GaN remaining on the wafer is removed by wet etching using hydrochloric acid or the like or by dry etching using an ICP apparatus to expose the n-type semiconductor layer 35. In this step S9, the non-doped layer 36 is removed to leave the LED layer 30 in which the p-type semiconductor layer 32, the p-type semiconductor layer 31, the light-emitting layer 33, and the n-type semiconductor layer 35 are laminated in this order.

This step S6 corresponds to the step (f).

### (Step S7)

Next, referring to FIG. 4G, adjacent elements are separated from each other. More specifically, with respect to a boundary region to an adjacent element, the LED layer 30 is etched using an ICP apparatus until the conductive oxide film layer 38 is exposed. This separates the LED layers 30 of adjacent regions from each other.

### (Step S8)

Next, referring to FIG. 4H, an undulation is formed on the front surface of the n-type semiconductor layer 35. More specifically, the undulation is formed by immersion into an alkali solution such as KOH. At this time, a construction may be adopted in which the undulation is not formed at the sites where the electrodes 42 are to be formed later. By not forming the undulation at these sites, the front surface of the n-type semiconductor layer 35 at the sites where the electrodes are to be formed is smoothened. By smoothening the front surface of the n-type semiconductor layer 35 at the sites where the electrodes are to be formed, an effect of preventing generation of voids at the interface between the electrodes 42 and the n-type semiconductor layer 35 is obtained particularly in performing wire bonding after forming the electrodes 42.

### (Step S9)

Next, referring to FIG. 4I, an electrode 42 is formed on the upper surface of the n-type semiconductor layer 35. More specifically, after forming an electrode made of Cr having a film thickness of 100 nm and Au having a film thickness of 3 μm, sintering is carried out at 250° C. for 1 minute in a nitrogen atmosphere. This step S9 corresponds to the step (g).

### (Step S10)

Next, the side surface of the element and the upper surface other than the electrode 42 where it is planned to perform wire bonding are covered with an insulating layer 41. More specifically, an SiO₂ film is formed using an EB apparatus. An SiN film may be formed as well. This allows that the LED element 1 shown in FIG. 1 is formed.

As subsequent steps, the elements are separated from each other using, for example, a laser dicing apparatus; the back surface of the support substrate 11 is joined to a package using, for example, an Ag paste; and wire bonding is carried out on some of the electrodes 42.

### [Method for Producing LED Element 1A]

Next, a method for producing the LED element 1A shown in FIG. 3A will be described.

In the same manner as in the method for producing the LED element 1, the steps S1 to S2 described above are carried out.

Further, in the step S3, an oxide conductive light-permeable material is deposited by sputtering at a high output of 300 W or more. This allows that the vicinity of the front surface of the p-type semiconductor layer 32 can be changed to be amorphous while depositing the conductive oxide film layer 38, whereby a Schottky barrier layer 32A is formed at the interface between the p-type semiconductor layer 32 and the conductive oxide film layer 38 (See FIG. 4J).

As another method, after the step S2, reverse sputtering of letting positive ions (for example, Ar⁺) collide onto the front surface of the p-type semiconductor layer 32 in a state in which the p-type semiconductor layer 32 side is kept at a negative potential is carried out (corresponding to step (h)). By this step, the vicinity of the front surface of the p-type semiconductor layer 32 can be changed to be amorphous in the same manner as described above. Thereafter, the conductive oxide film layer 38 is deposited on the upper layer of the p-type semiconductor layer 32 in the same manner as in the step S3. By this method as well, a Schottky barrier layer 32A is formed at the interface between the p-type semiconductor layer 32 and the conductive oxide film layer 38.

The step S4 and the subsequent steps are similar to those of the LED element 1, so that the description thereof will be omitted.

### [Method for Producing LED Element 1B]

Next, a method for producing the LED element 1B shown in FIG. 3B will be described.

In the same manner as in the method for producing the LED element 1, the steps S1 to S2 described above are carried out.

Next, referring to FIG. 4K, an insulating layer 39 is formed at a predetermined site (second predetermined site) of an upper layer of the p-type semiconductor layer 32 (step S2A). This second predetermined site corresponds to a region on a wafer that is subject to etching at the time of element separation in the step S7 carried out later, that is, the outer peripheries of the element. This step S2A corresponds to the step (i).

Thereafter, referring to FIG. 4L, the conductive oxide film layer 38 is formed in the same manner as in the above-described step S3. The subsequent steps are similar to those of the LED element 1.

Here, at the time of producing the LED element 1B, the step S7 is a step of etching the LED layer 30 until the insulating layer 39 instead of the conductive oxide film layer 38 is exposed (corresponding to step (j): See FIG. 4M), unlike the case of the LED element 1. By this method, the insulating layer 39 is formed immediately below the LED layer 30 at the site subject to etching at the time of the start of the step S7, so that this insulating layer 39 functions also as an etching stopper layer. In other words, the etching step can be easily stopped at the time point at which the upper surface of the insulating layer 39 is exposed. Also, the conductive oxide film layer 38 is not etched, thereby eliminating a fear that the conductive material adheres onto the side wall of the LED layer 30 through etching.

### Other Embodiments

Hereafter, other embodiments will be described.

<1> In the above-described embodiment, the protective layer 17 is formed on the sapphire substrate 61 side; however, the protective layer 17 may be formed on the support substrate 11 side as well. In other words, instead of the construction shown in FIG. 4D, the one in which the protective layer 17 is formed on the upper layer of the support substrate 11 and the solder layer 13 is formed thereon may be bonded to the sapphire substrate 61 in the step S8.
<2> In the above-described embodiment, solder layers are formed both on the sapphire substrate 61 and on the support substrate 11 (solder layers 13, 15); however, the two substrates may be bonded to each other after a solder layer is formed on only one of the two substrates.
<3> The structures shown in FIG. 1 and FIGS. 3A to 3D and the production methods shown in FIGS. 4A to 4M and FIG. 5 are examples of preferable embodiments, so that there is no need to provide all of these constructions and processes. For example, the solder layer 13 and the solder layer 15 are formed for efficiently performing the bonding of two substrates, so that the solder layer 13 and the solder layer 15 are not necessarily needed in achieving the function of the LED element 1 (1A, 1B, 1C) as long as the bonding of the two substrates can be achieved.

The reflective electrode 19 is preferably provided from the viewpoint of further improving the extraction efficiency of the light radiated from the light-emitting layer 33; however, there is not necessarily a need to provide the reflective electrode 19. The same applies to the protective layer 17, the undulation on the front surface of the n-type semiconductor layer 35, and the like as well.

### DESCRIPTION OF REFERENCE SIGNS

1, 1A, 1B, 1C: LED element
11: support substrate
13: solder layer
15: solder layer
17: protective layer
19: reflective electrode
20: conductive layer
30: LED layer
31: (low-concentration) p-type semiconductor layer
32: (high-concentration) p-type semiconductor layer <contact layer>
32A: Schottky barrier layer
33: light-emitting layer
35: n-type semiconductor layer
36: non-doped layer
38: conductive oxide film layer
39: insulating layer
40: LED epi-layer
41: insulating layer
42: electrode
61: sapphire substrate

1. An LED element containing a nitride semiconductor, comprising:
a support substrate made of a conductor or a semiconductor;
a conductive layer formed on the upper layer of the support substrate;
a conductive oxide film layer formed on the upper layer of the conductive layer;
a first semiconductor layer made of a p-type nitride semiconductor formed so that a bottom surface of the first semiconductor layer is in contact with a portion of an upper surface of the conductive layer and a portion of an upper surface of the conductive oxide film layer;
a second semiconductor layer formed on the upper layer of the first semiconductor layer and made of a p-type nitride semiconductor having a lower concentration than that of the first semiconductor layer;
a light-emitting layer made of a nitride semiconductor formed on the upper layer of the second semiconductor layer;
a third semiconductor layer made of an n-type nitride semiconductor formed on the upper layer of the light-emitting layer; and
an electrode formed at a position facing the conductive oxide film layer in a vertical direction so that a bottom surface of the electrode is in contact with a portion of an upper surface of the third semiconductor layer, wherein
the conductive oxide film layer is made of a material having a thermal expansion coefficient of 1×10⁻⁶/K or more and 1×10⁻⁵/K or less.

2. The LED element according to claim 1, wherein a Schottky barrier layer is formed at an interface between the conductive oxide film layer and the first semiconductor layer.

3. The LED element according to claim 1, wherein the support substrate and the conductive layer are formed to be wider in a horizontal direction than an LED layer including the first semiconductor layer, the second semiconductor layer, the light-emitting layer, and the third semiconductor layer, and
the LED element has an insulating layer formed at a position that protrudes in a horizontal direction from the LED layer so that a bottom surface of the insulating layer is in contact with an upper surface of the conductive oxide film layer or the conductive layer.

4. The LED element according to claim 1, wherein the conductive layer has a reflective electrode as an uppermost layer of the conductive layer and is formed so that an upper surface of the reflective electrode is in contact with a portion of a bottom surface of the first semiconductor layer and in contact with a bottom surface of the conductive oxide film layer, and
the conductive oxide film layer is made of a transparent electrode.

5. The LED element according to claim 1, wherein the conductive oxide film layer is made of a material having a thermal expansion coefficient of 3×10⁻⁶/K or more and 8×10⁻⁶/K or less.

6. A method for producing an LED element having a first semiconductor layer made of a p-type nitride semiconductor, a second semiconductor layer made of a p-type nitride semiconductor having a lower concentration than that of the first semiconductor layer, a light-emitting layer made of a nitride semiconductor, and a third semiconductor layer made of an n-type nitride semiconductor, comprising:
a step (a) of preparing a sapphire substrate;
a step (b) of forming the third semiconductor layer, the light-emitting layer, the second semiconductor layer, and the first semiconductor layer on the upper layer of the sapphire substrate in this order from below;
a step (c) of forming a conductive oxide film layer made of a material having a thermal expansion coefficient of 1×10⁻⁶/K or more and 1×10⁻⁵/K or less at a first predetermined site of an upper layer of the first semiconductor layer;
a step (d) of forming a conductive layer so as to cover an exposed portion of an upper surface of the first semiconductor layer and an upper surface of the conductive oxide film layer;
a step (e) of bonding a bottom surface of a support substrate made of a conductor or a semiconductor onto an upper surface of the conductive layer directly or via another conductive layer;
a step (f) of exfoliating the sapphire substrate by radiating laser light from above in a state in which the support substrate is positioned at a bottom and the sapphire substrate is positioned at a top, so as to expose an upper surface of the third semiconductor layer; and
a step (g) of forming an electrode on the upper layer of the third semiconductor layer at a position above the first predetermined site.

7. The method for producing an LED element according to claim 6, wherein the step (c) is a step of sputtering the material that forms the conductive oxide film layer, and a Schottky barrier layer is formed at an interface between the first semiconductor layer and the conductive oxide film layer by the sputtering step.

8. The method for producing an LED element according to claim 6, comprising a step (h) of forming, after the step (b), a Schottky barrier layer by performing a reverse sputtering treatment on a front surface of the first semiconductor layer at the first predetermined site where it is planned to form the conductive oxide film layer in the step (c), wherein the step (c) is carried out after the step (h).

9. The method for producing an LED element according to claim 6, comprising:
a step (i) of forming an insulating layer at a second predetermined site located at an edge of an upper layer of the first semiconductor layer after the step (b) and before the step (c), and
a step (j) of etching the third semiconductor layer, the light-emitting layer, the second semiconductor layer, and the first semiconductor layer formed above the second predetermined site, so as to expose an upper surface of the insulating layer after the step (f) and before the step (g).

10. The method for producing an LED element according to claim 6, wherein
the step (c) is a step of forming a transparent electrode as the conductive oxide film layer, and
the step (d) has a step of forming a reflective electrode so as to cover an upper surface of the first semiconductor layer and an upper surface of the conductive oxide film layer, a step of forming a protective layer on the upper layer of the reflective electrode, and a step of forming a solder layer on the upper layer of the protective layer, and is a step of forming the conductive layer including the reflective electrode, the protective layer, and the solder layer.

11. The LED element according to claim 2, wherein the support substrate and the conductive layer are formed to be wider in a horizontal direction than an LED layer including the first semiconductor layer, the second semiconductor layer, the light-emitting layer, and the third semiconductor layer, and
the LED element has an insulating layer formed at a position that protrudes in a horizontal direction from the LED layer so that a bottom surface of the insulating layer is in contact with an upper surface of the conductive oxide film layer or the conductive layer.

12. The LED element according to claim 2, wherein the conductive layer has a reflective electrode as an uppermost layer of the conductive layer and is formed so that an upper surface of the reflective electrode is in contact with a portion of a bottom surface of the first semiconductor layer and in contact with a bottom surface of the conductive oxide film layer, and
the conductive oxide film layer is made of a transparent electrode.

13. The LED element according to claim 3, wherein the conductive layer has a reflective electrode as an uppermost layer of the conductive layer and is formed so that an upper surface of the reflective electrode is in contact with a portion of a bottom surface of the first semiconductor layer and in contact with a bottom surface of the conductive oxide film layer, and
the conductive oxide film layer is made of a transparent electrode.

14. The LED element according to claim 2, wherein the conductive oxide film layer is made of a material having a thermal expansion coefficient of 3×10⁻⁶/K or more and 8×10⁻⁶/K or less.

15. The LED element according to claim 3, wherein the conductive oxide film layer is made of a material having a thermal expansion coefficient of 3×10⁻⁶/K or more and 8×10⁻⁶/K or less.

16. The LED element according to claim 4, wherein the conductive oxide film layer is made of a material having a thermal expansion coefficient of 3×10⁻⁶/K or more and 8×10⁻⁶/K or less.

17. The LED element according to claim 11, wherein the conductive oxide film layer is made of a material having a thermal expansion coefficient of 3×10⁻⁶/K or more and 8×10⁻⁶/K or less.

18. The LED element according to claim 12, wherein the conductive oxide film layer is made of a material having a thermal expansion coefficient of 3×10⁻⁶/K or more and 8×10⁻⁶/K or less.

19. The LED element according to claim 13, wherein the conductive oxide film layer is made of a material having a thermal expansion coefficient of 3×10⁻⁶/K or more and 8×10⁻⁶/K or less.
